(19) United States
(12) Patent Application Publication
(10) Pub. No.: US 2016/0359116 A1
(43) Pub. Date: Dec. 8, 2016

(54) Organic Semiconductor Formulations

(71) Applicant: SMARTKEM LIMITED, Blackley Manchester (GB)

(72) Inventors: Karl Crowley, St Asaph, Clwyd (GB); Russell Jon Griffiths, Farnworth Bolton (GB)

(21) Appl. No.: 14/646,787

(22) PCT Filed: Nov. 26, 2013
(86) PCT No.: PCT/GB13/53123

§ 371 Date: May 22, 2015

(30) Foreign Application Priority Data
Nov. 29, 2012 (GB) 1221471.4

(51) Int. Cl. H01L 51/00; C08G 73/02; C09D 179/02; C09D 5/24; C08L 79/02

(52) U.S. Cl. CPC H01L 51/0035; H01L 51/0003; C09D 5/24; H01L 51/0043; C08L 79/02; C09D 179/02; C08G 73/026; H01L 51/0558

(57) ABSTRACT

The present invention relates to a process for preparing novel organic semiconductor (OSC) formulations including a polycrystalline small molecule organic semiconductor, a semiconducting polymer binder, and a multi-component solvent blend. The present invention also relates to novel formulations obtained by this process, to their use as semiconducting inks in the fabrication of organic electronic devices, especially organic thin film transistors (OTFTs).

### FIELD OF THE INVENTION

The present invention relates to a process for preparing novel organic semiconductor (OSC) formulations comprising a polycrystalline small molecule organic semiconductor, a semiconducting polymer binder and a multi-component solvent blend. The present invention also relates to novel formulations obtained by this process, to their use as semiconducting inks in the fabrication of organic electronic devices, especially organic thin film transistors (OTFTs).

In accordance with the main aspects of the invention, during the fabrication of OTFTs, the blended organic semiconductor formulation is deposited onto a substrate to yield a continuous semiconductor film having better crystal morphology than films produced from the corresponding single solvent/semiconducting material formulation under similar deposition conditions. The improved transistor performance resulting from the multi-solvent formulation is manifested as significantly higher mobility in both Top Gate and Bottom Gate Transistors even at short channel lengths (≦10 microns); improved OTFT to OTFT uniformity across the array and lower threshold voltage values.

Presented in the invention are novel multi-solvent organic semiconducting formulations having significantly improved electrical performance in OTFTs. The OSC formulations of the invention will be industrially useful in the fabrication of flexible electronic devices such as displays; large area printed sensors and printed logic. In particular, the multi-solvent formulations of this invention will be useful in the industrial manufacture of OTFTs having short channel lengths (<10 microns and even <5 microns), these will find use as the backplane driver for high resolution OLED and ultra-high definition liquid crystal displays.

### SUMMARY OF THE INVENTION

The multi-solvent OSC formulation according to the present invention comprises:
(a) a polycrystalline small molecule organic semiconductor;
(b) an organic semiconductor binder;
(c) an aromatic hydrocarbon solvent; and
(d) at least one further solvent selected from the group consisting of aliphatic hydrocarbons, alcohols, polyols, esters, amines, thiols and/or combinations thereof.

The multi-solvent OSC formulation offer one or more of the following beneficial features:
1. Enables fabrication of OTFTs having much higher mobility than the corresponding single solvent formulation at all TFT channel lengths; this is particularly beneficial at short channel length (≦10 microns).
2. Affords very high mobility Bottom Gate OTFTs which has hitherto been a problem in the field of printed electronics when using polycrystalline small molecule OSC-binder formulations. The ease of preparing top gate OTFTs from small molecule/binder blends was previously reported by Brown et al. in patent application WO2005/055248. The technical approach described in WO2005/055248 is however ineffective in the fabrication of bottom gate OTFTs as corroborated by Kang et al. in J. Am. Chem. Soc. 2008, 130, pp 12273-12275. This invention overcomes the previous problems associated with preparing high performance bottom gate OTFTs from small molecule/binder organic semiconductor formulations.
3. Affords high mobility top gate OTFTs (μ≧5 cm²·V⁻¹ s⁻¹ @ channel length L, ≦30 microns)
4. Affords OTFTs having improved threshold voltage values (Vth≦10V)
5. Affords better OTFT uniformity across the printed TFT array (uniformity better than 5% across 4×4 inch TFT array).
6. Affords fully flexible, foldable, non-brittle semiconducting films

### Organic Semiconductor Molecule

The polycrystalline small molecule organic semiconductor used in the present invention is preferably a polyacene compound of Formula (1):

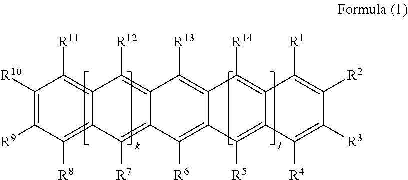

wherein each of R¹, R², R³, R⁴, R⁵, R⁶, R⁷, R⁸, R⁹, R¹⁰, R¹¹, R¹², R¹³ and R¹⁴, which may be the same or different, independently represents hydrogen; a branched or unbranched, substituted or unsubstituted C₁-C₄₀ alkyl group; a branched or unbranched, substituted or unsubstituted C₂-C₄₀ alkenyl group; a branched or unbranched, substituted or unsubstituted C₂-C₄₀ alkynyl group; an optionally substituted C₃-C₄₀ cycloalkyl group; an optionally substituted C₆-C₄₀ aryl group; an optionally substituted C₁-C₄₀ heterocyclic group; an optionally substituted C₁-C₄₀ heteroaryl group; an optionally substituted C₁-C₄₀ alkoxy group; an optionally substituted C₆-C₄₀ aryloxy group; an optionally substituted C₇-C₄₀ alkylaryloxy group; an optionally substituted C₂-C₄₀ alkoxycarbonyl group; an optionally substituted C₇-C₄₀ aryloxycarbonyl group; a cyano group (—CN); a carbamoyl group (—C(═O)NR¹⁵R¹⁶); a carbonyl group (—OC(═O)—R¹⁷); a carboxyl group (—CO₂R¹⁸) a cyanate group (—OCN); an isocyano group (—NC); an isocyanate group (—NCO); a thiocyanate group (—SCN) or a thioisocyanate group (—NCS); an optionally substituted amino group; a hydroxy group; a nitro group; a CF₃ group; a halo group (Cl, Br, F, I); —SR¹⁹; —SO₃H; —SO₂R²⁰; —SF₅; an optionally substituted silyl group; a C₂-C₁₀ alkynyl group substituted with a SiH₂R²² group, a C₂-C₁₀ alkynyl substituted with a SiHR²² R²³ group, or a C₂-C₁₀ alkynyl substituted with a SiR²²R²³R²⁴ group;
wherein each of R¹⁵, R¹⁶, R¹⁸, R¹⁹ and R²⁰ independently represent H or optionally substituted C₁-C₄₀ carbyl or hydrocarbyl group optionally comprising one or more heteroatoms;
wherein R¹⁷ represents a halogen atom, H or optionally substituted C₁-C₄₀ carbyl or C₁-C₄₀ hydrocarbyl group optionally comprising one or more heteroatoms;
wherein, independently, each pair of R² and R³ and/or R⁹ and R¹⁰, may be cross-bridged to form a C₄—O₄₀ saturated or unsaturated ring, which saturated or unsaturated ring may be intervened by an oxygen atom, a sulphur atom or a group shown by formula —N(R²¹)— (wherein R²¹ is a hydrogen atom or an optionally substituted C₁-C₄₀ hydrocarbon group), or may optionally be substituted; and wherein one or more of the carbon atoms of the polyacene skeleton may optionally be substituted by a heteroatom selected from N, P, As, O, S, Se and Te;
wherein R²², R²³ and R²⁴ are independently selected from the group consisting of hydrogen, a C₁-C₄₀ alkyl group which may optionally be substituted for example with a halogen atom; a C₆-C₄₀ aryl group which may optionally be substituted for example with a halogen atom; a C₇-C₄₀ arylalkyl group which may optionally be substituted for example with a halogen atom; a C₁-C₄₀ alkoxy group which may optionally be substituted for example with a halogen atom; or a C₇-C₄₀ arylalkyloxy group which may optionally be substituted for example with a halogen atom;
wherein independently any two or more of the substituents R¹-R¹⁴ which are located on adjacent ring positions of the polyacene may, together, optionally constitute a further C₄-C₄₀ saturated or unsaturated ring optionally interrupted by O, S or —N(R²¹) where R²¹ is as defined above; or an aromatic ring system, fused to the polyacene; and
wherein k and I are independently 0, 1 or 2.

Preferably, k=I=0 or 1.

Preferably, k=1 and I=1.

In a preferred embodiment, at least one (and more preferably 2) of groups R¹, R², R³, R⁴, R⁵, R⁶, R⁷, R⁸, R⁹, R¹⁰, R¹¹, R¹², R¹³ and R¹⁴ are tri-C₁₋₂₀hydrocarbylsilyl C₁₋₄alkynyl groups (i.e., C₁₋₂₀ hydrocarbyl-SiR²²R²³R²⁴), wherein R²², R²³ and R²⁴ independently represent C₁-C₆ alkyl or C₂-C₆ alkenyl.

In a preferred embodiment, at least one (and more preferably 2) of groups R¹, R², R³, R⁴, R⁵, R⁶, R⁷, R⁸, R⁹, R¹⁰, R¹¹, R¹², R¹³ and R¹⁴ are trihydrocarbylsilylethynyl groups (—C≡C—SiR²²R²³R²⁴), wherein R²², R²³ and R²⁴ independently represent C₁-C₆ alkyl or C₂-C₆ alkenyl. In a more preferred embodiment, R²², R²³ and R²⁴ are independently selected from the group consisting of methyl, ethyl, propyl, isopropyl, n-butyl, isobutyl, t-butyl, 1-propenyl and 2-propenyl.

In a preferred embodiment, R⁶ and R¹³ are trialkylsilylethynyl groups (—C≡C—SiR²²R²³R²⁴), wherein R²², R²³ and R²⁴ independently represent C₁-C₆ alkyl or C₂-C₆ alkenyl. In a more preferred embodiment, R²², R²³ and R²⁴ are independently selected from the group consisting of methyl, ethyl, propyl, isopropyl, n-butyl, isobutyl, t-butyl 1-propenyl and 2-propenyl.

In yet another preferred embodiment, when k=I=1; R¹, R², R³, R⁴, R⁸, R⁹, R¹⁰ and R¹¹ independently represent H, C₁-C₆ alkyl or C₁-C₆ alkoxy. More preferably, R¹, R⁴, R⁸ and R¹¹ are the same and represent H, C₁-C₆ alkyl or C₁-C₆ alkoxy. In an even more preferred embodiment, R¹, R², R³, R⁴, R⁸, R⁹, R¹⁰ and R¹¹ are the same or different and are selected from the group consisting of hydrogen, methyl, ethyl, propyl, n-butyl, isobutyl, t-butyl, methoxy, ethoxy, propyloxy and butyloxy.

In yet another embodiment, when k=I=0 or 1, independently each pair of R² and R³ and/or R⁹ and R¹⁰, are cross-bridged to form a C₄-C₁₀ saturated or unsaturated ring, which saturated or unsaturated ring may be intervened by an oxygen atom, a sulphur atom or a group shown by formula —N(R²¹)— (wherein R²¹ is a hydrogen atom or a cyclic, straight chain or branched C₁-C₁₀ alkyl group); and wherein one or more of the carbon atoms of the polyacene skeleton may optionally be substituted by a heteroatom selected from N, P, As, O, S, Se and Te.

Preferably, R⁵, R⁷, R¹² and R¹⁴ are hydrogen.

Preferably, R²², R²³ and R²⁴ are independently selected from the group consisting hydrogen, a C₁-C₁₀ alkyl group (preferably C₁-C₄-alkyl and most preferably methyl, ethyl, n-propyl or isopropyl) which may optionally be substituted for example with a halogen atom; a C₆-C₁₂ aryl group (preferably phenyl) which may optionally be substituted for example with a halogen atom; a C₇-C₁₆ arylalkyl group which may optionally be substituted for example with a halogen atom; a C₁-C₁₀ alkoxy group which may optionally be substituted for example with a halogen atom; or a C₇-C₁₆ arylalkyloxy group which may optionally be substituted for example with a halogen atom.

R²², R²³ and R²⁴ are preferably independently selected from the group consisting optionally substituted C₁₋₁₀ alkyl group and optionally substituted C₂₋₁₀ alkenyl, more preferably C₁-C₆ alkyl or C₂-C₆ alkenyl. A preferred alkyl group in this case is isopropyl.

Examples of the silyl group —SiR²²R²³R²⁴ include, without limitation, trimethylsilyl, triethylsilyl, tripropylsilyl, dimethylethylsilyl, diethylmethylsilyl, dimethylpropylsilyl, dimethylisopropylsilyl, dipropylmethylsilyl, diisopropylmethylsilyl, dipropylethylsilyl, diisopropylethylsilyl, diethylisopropylsilyl, triisopropylsilyl, trimethoxysilyl, triethoxysilyl, triphenylsilyl, diphenylisopropylsilyl, diisopropylphenylsilyl, diphenylethylsilyl, diethylphenylsilyl, diphenylmethylsilyl, triphenoxysilyl, dimethylmethoxysilyl, dimethylphenoxysilyl, methylmethoxyphenyl, etc. For each example in the foregoing list, the alkyl, aryl or alkoxy group may optionally be substituted.

In a preferred embodiment, polyacene compounds according to the present invention are of Formula (1a):

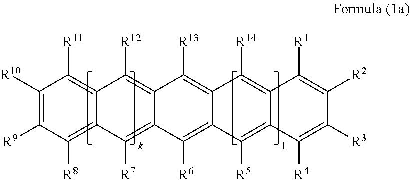

wherein each of R⁵, R⁷, R¹² and R¹⁴ are hydrogen;
R⁶ and R¹³ are trialkylsilylethynyl groups (—C≡C—SiR²²R²³R²⁴), wherein R²², R²³ and R²⁴ independently represent C₁-C₄ alkyl or C₂-C₄ alkenyl;
R¹, R², R³, R⁴, R⁸, R⁹, R¹⁰ and R¹¹ are independently selected from the group consisting of hydrogen; a branched or unbranched, unsubstituted C₁-C₄ alkyl group; C₁-C₆ alkoxy group and C₆-C₁₂aryloxy group;
or wherein independently each pair of R² and R³ and/or R⁹ and R¹⁰, may be cross-bridged to form a C₄-C₁₀ saturated or unsaturated ring, which saturated or unsaturated ring may be intervened by an oxygen atom, a sulphur atom or a group shown by formula —N(R²¹)— (wherein R²¹ is a hydrogen atom or an optionally substituted C₁-C₆ alkyl group);
wherein k and I are independently 0, or 1, preferably both k and I are 1.

In compounds of Formula (1a), wherein k and I are both 1; R⁶ and R¹³ are trialkylsilylethynyl groups (—C≡C—SiR²²R²³R²⁴), wherein R²², R²³ and R²⁴ are preferably selected from ethyl, n-propyl, isopropyl, 1-propenyl or 2-propenyl; R¹, R², R³, R⁴, R⁸, R⁹, R¹⁰ and R¹¹ are independently selected from the group consisting of hydrogen, methyl, ethyl and methoxy.

In compounds of Formula (1a), wherein k and I are both 0; R⁶ and R¹³ are preferably trialkylsilylethynyl groups (—C≡C—SiR²²R²³R²⁴), wherein R²², R²³ and R²⁴ are preferably selected from ethyl, n-propyl, isopropyl, 1-propenyl or 2-propenyl; R¹, R⁴, R⁸ and R¹¹ are preferably hydrogen; and R² and R³ together, and R⁹ and R¹⁰ together preferably form 5-membered heterocyclic rings containing 1 or 2 nitrogen atoms, 1 or 2 sulphur atoms or 1 or 2 oxygen atoms.

Especially preferred polyacene compounds used in the present invention are those of Formulae (2) and (3):

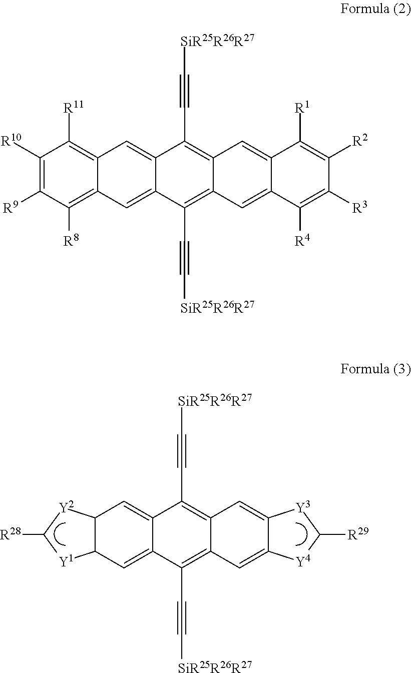

wherein R¹, R⁴, R⁸ and R¹¹ are independently selected from the group consisting of H, C₁-C₆ alkyl and C₁-C₆ alkoxy. Preferably R¹, R⁴, R⁸ and R¹¹ are the same or different and are independently selected from the group consisting of hydrogen, methyl, ethyl, propyl, n-butyl, isobutyl, t-butyl, methoxy, ethoxy, propyloxy and butyloxy, more preferably hydrogen, methyl, propyl and methoxy.

In compounds of Formula (2), R², R³, R⁹ and R¹⁰ are independently selected from the group consisting of H, C₁-C₆ alkyl and C₁-C₆ alkoxy, or each pair of R² and R³ and/or R⁹ and R¹⁰, are cross-bridged to form a C₄-C₁₀ saturated or unsaturated ring, which saturated or unsaturated ring may be intervened by an oxygen atom, a sulphur atom or a group shown by formula —N(R²¹)— (wherein R²¹ is a hydrogen atom or a cyclic, straight chain or branched C₁-C₁₀ alkyl group); and wherein one or more of the carbon atoms of the polyacene skeleton may optionally be substituted by a heteroatom selected from N, P, As, O, S, Se and Te. In a preferred embodiment, R², R³, R⁹ and R¹⁰ are the same or different and are independently selected from the group consisting of hydrogen, methyl, ethyl, propyl, n-butyl, isobutyl, t-butyl, methoxy, ethoxy, propyloxy and butyloxy, more preferably hydrogen, methyl, ethyl, propyl and methoxy; In compounds of Formulae (2) and (3), R²⁵, R²⁶ and R²⁷ are independently selected from the group consisting of C₁-C₆ alkyl and C₂-C₆ alkenyl, preferably R²², R²³ and R²⁴ are independently selected from the group consisting of methyl, ethyl, propyl, isopropyl, n-butyl, isobutyl, t-butyl, 1-propenyl and 2-propenyl, more preferably ethyl, n-propyl and isopropyl.

In compounds of Formula (3), R²⁸ and R²⁹ are independently selected from the group consisting of hydrogen, halogen, —CN, optionally fluorinated or perfluorinated, straight chain or branched C₁-C₂₀ alkyl, fluorinated or perfluorinated, straight chain or branched C₁-C₂₀ alkoxy, fluorinated or perfluorinated C₆-C₃₀ aryl and CO₂R³⁰, wherein R³⁰ is H, fluorinated or perfluorinated, straight chain or branched C₁-C₂₀ alkyl, and fluorinated or perfluorinated C₆-C₃₀ aryl. Preferably R²⁸ and R²⁹ are independently selected from the group consisting of fluorinated or perfluorinated, straight chain or branched C₁-C₈ alkyl, fluorinated or perfluorinated, straight chain or branched C₁-C₈ alkoxy and C₆F₅.

In compounds of Formula (3), Y¹, Y², Y³ and Y⁴ are preferably independently selected from the group consisting of —CH═, ═CH—, O, S, Se or NR³¹ (wherein R³¹ is a hydrogen atom or a cyclic, straight chain or branched C₁-C₁₀ alkyl group).

In yet another preferred embodiment, the polyacene compounds of the present invention are those of Formulae (4) and (5):

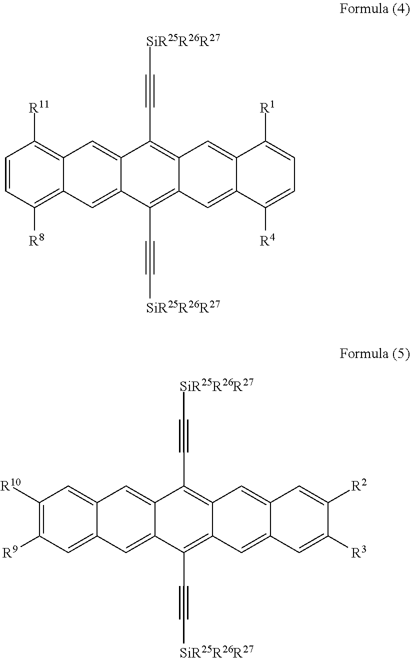

wherein R²⁵, R²⁶ and R²⁷ are independently selected from the group consisting of methyl, ethyl and isopropyl;
wherein R¹, R², R³, R⁴, R⁸, R⁹, R¹⁰ and R¹¹ are independently selected from the group consisting of C₁-C₆ alkyl, C₁-C₆ alkoxy and C₆-C₂₀ aryloxy. Preferably R¹, R², R³, R⁴, R⁸, R⁹, R¹⁰ and R¹¹ are independently selected from the group consisting of methyl, ethyl, propyl, n-butyl, isobutyl, t-butyl, methoxy, ethoxy, propyloxy and butyloxy groups.

In some preferred embodiments, when R¹, R⁴, R⁸ and R¹¹ are the same and are methyl or methoxy groups, R²⁵, R²⁶ and R²⁷ are the same and are ethyl or isopropyl groups. In a preferred embodiment, when R¹, R⁴, R⁸ and R¹¹ are methyl groups, R²⁵, R²⁶ and R²⁷ are ethyl groups. In yet another a preferred embodiment, when R¹, R⁴, R⁸ and R¹¹ are methyl groups, R²⁵, R²⁶ and R²⁷ are isopropyl groups. In a further preferred embodiment, when R¹, R⁴, R⁸ and R¹¹ are methoxy groups, R²⁵, R²⁶ and R²⁷ are ethyl groups. In yet another preferred embodiment, when R¹, R⁴, R⁸ and R¹¹ are methoxy groups, R²⁵, R²⁶ and R²⁷ are isopropyl groups.

In some preferred embodiments when R², R³, R⁹ and R¹⁰ are the same and are methyl or methoxy groups, R²⁵, R²⁶ and R²⁷ are the same and are ethyl or isopropyl groups. In a preferred embodiment, when R², R³, R⁹ and R¹⁰ are methyl groups, R²⁵, R²⁶ and R²⁷ are ethyl groups. In yet another a preferred embodiment, when R², R³, R⁹ and R¹⁰ are methyl groups, R²⁵, R²⁶ and R²⁷ are isopropyl groups. In a further preferred embodiment, when R², R³, R⁹ and R¹⁰ are methoxy groups, R²⁵, R²⁶ and R²⁷ are ethyl groups. In yet another preferred embodiment, when R², R³, R⁹ and R¹⁰ are methoxy groups, R²⁵, R²⁶ and R²⁷ are isopropyl groups.

In an even more preferred embodiment of the present invention, the polyacene compound is selected from the following compounds (A) to (F):

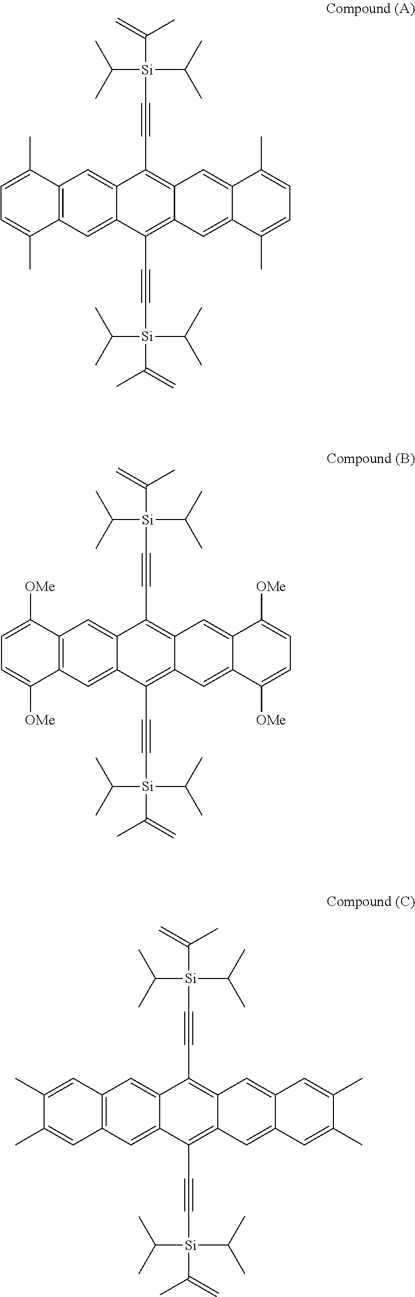

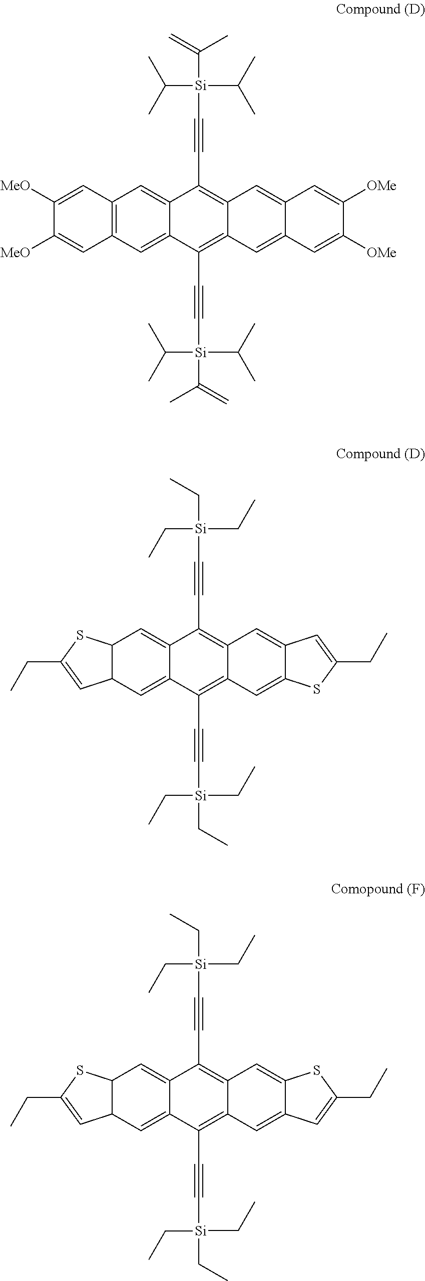

The “R” substituents (that is R¹, R², etc) denote the substituents at the positions of pentacene according to conventional nomenclature:

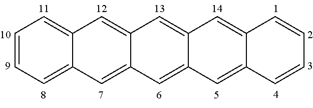 [SMILES: c1ccc2cc3cc4cc5ccccc5cc4cc3cc2c1]

Polyacene compounds used in the present invention may be synthesised by any known method within the common general knowledge of a person skilled in the art. In a preferred embodiment, methods disclosed in US 2003/0116755 A, U.S. Pat. No. 3,557,233, U.S. Pat. No. 6,690,029 WO 2007/078993, WO 2008/128618 and Organic Letters, 2004, Volume 6, number 10, pages 1609-1612 can be employed for the synthesis of polyacene compounds according to the present invention.

### Organic Semiconducting Binder

An organic semiconducting binder used in the present invention may be a polytriarylamine binder comprising a unit of Formula (6):

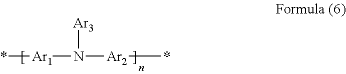

wherein Ar₁, Ar₂ and Ar₃, which may be the same or different, each represent, independently if in different repeat units, an optionally substituted C₆₋₄₀ aromatic group (mononuclear or polynuclear), wherein at least one of Ar₁, Ar₂ and Ar₃ is substituted with at least one polar or more polarising group, and n=1 to 20, preferably 1 to 10 and more preferably 1 to 5. Preferably, at least one of Ar₁, Ar₂ and Ar₃ is substituted with 1, 2, 3, or 4, more preferably 1, 2 or 3, more preferably 1 or 2, preferably 1 polar or more polarising group(s).

In a preferred embodiment, the one or more polar or polarising group(s) is independently selected from the group consisting of nitro group, nitrile group, C₁₋₄₀alkyl group substituted with a nitro group, a nitrile group, a cyanate group, an isocyanate group, a thiocyanate group or a thioisocyanate group; C₁₋₄₀alkoxy group optionally substituted with a nitro group, a nitrile group, a cyanate group, an isocyanate group, a thiocyanate group or a thioisocyanate group; C₁₋₄₀carboxylic acid group optionally substituted with a nitro group, a nitrile group, a cyanate group, an isocyanate group, a thiocyanate group or a thioisocyanate group; C₂₋₄₀ carboxylic acid ester optionally substituted with a nitro group, a nitrile group, a cyanate group, an isocyanate group, a thiocyanate group or a thioisocyanate group; sulfonic acid optionally substituted with a nitro group, a nitrile group, a cyanate group, an isocyanate group, a thiocyanate group or a thioisocyanate group; sulfonic acid ester optionally substituted with a nitro group, a nitrile group, a cyanate group, an isocyanate group, a thiocyanate group or a thioisocyanate group; cyanate group, isocyanate group, thiocyanate group, thioisocyanate group; and an amino group optionally substituted with a nitro group, a nitrile group, a cyanate group, an isocyanate group, a thiocyanate group or a thioisocyanate group; and combinations thereof.

In a more preferred embodiment, the one or more polar or polarising group(s) is independently selected from the group consisting of nitro group, nitrile group, C₁₋₁₀alkyl group substituted with a nitrile group, a cyanate group, or an isocyanate group; C₁₋₂₀ alkoxy group, C₁₋₂₀carboxylic acid group, C₂₋₂₀ carboxylic acid ester; sulfonic acid ester; cyanate group, isocyanate group, thiocyanate group, thioisocyanate group, and an amino group; and combinations thereof.

More preferably the polar or polarizing group is selected from the group consisting of C₁₋₄ cyanoalkyl group, C₁₋₁₀ alkoxy group, nitrile group and combinations thereof.

More preferably the polar or polarizing group is selected from the group consisting of cyanomethyl, cyanoethyl, cyanopropyl, cyanobutyl, methoxy, ethoxy, propoxy, butoxy, nitrile, NH₂ and combinations thereof. Preferably at least one of Ar₁, Ar₂ and Ar₃ is substituted with 1 or 2 polar or more polarising group, which may be the same or different.

In the context of Ar₁, Ar₂ and Ar₃, a mononuclear aromatic group has only one aromatic ring, for example phenyl or phenylene. A polynuclear aromatic group has two or more aromatic rings which may be fused (for example napthyl or naphthylene), individually covalently linked (for example biphenyl) and/or a combination of both fused and individually linked aromatic rings. Preferably each Ar₁, Ar₂ and Ar₃ is an aromatic group which is substantially conjugated over substantially the whole group.

Preferably, Ar₁, Ar₂ and Ar₃, are independently selected from the group consisting of C₆₋₂₀ aryl, C₇₋₂₀ aralkyl and C₇₋₂₀ alkaryl, any of which may be substituted with 1, 2, or 3 groups independently selected from C₁₋₄ alkoxy, C₁₋₄ cyanoalkyl, CN and mixtures thereof, and n=1 to 10.

Preferably, Ar₁, Ar₂ and Ar₃, are independently selected from the group consisting of C₆₋₁₀ aryl, C₇₋₁₂ aralkyl and C₇₋₁₂ alkaryl, any of which may be substituted with 1, 2, or 3 groups independently selected from C₁₋₂ alkoxy, C₁₋₃ cyanoalkyl, CN and mixtures thereof, and n=1 to 10.

Preferably, Ar₁, Ar₂ and Ar₃, are independently selected from the group consisting of phenyl, benzyl, tolyl and naphthyl, any of which may be substituted with 1, 2 or 3 groups independently selected from methoxy, ethoxy, cyanomethyl, cyanoethyl, CN and mixtures thereof, and n=1 to 10.

Preferably, Ar₁, Ar₂ and Ar₃, are all phenyl which may be independently substituted with 1, 2 or 3 groups selected from methoxy, ethoxy, cyanomethyl, cyanoethyl, CN and mixtures thereof, and n=1 to 10.

Preferably, Ar₁, Ar₂ and Ar₃, are all phenyl which may be independently substituted with 1 or 2 groups selected from methoxy, cyanomethyl, CN and mixtures thereof, and n=1 to 10.

In a further preferred embodiment, the organic binder may be a random or block copolymer of different triarylamine monomers. In such a case, any compound as defined by Formula (6) may be combined with a different compound of Formula (6) to provide the random or block copolymer according to the present invention. For example, the organic binder may be a copolymer of a nitro-substituted triarylamine with a 2,4-dimethyl substituted triarylamine. The ratio of the monomers in the polymers can be altered to allow for adjustment of the permittivity relative to a homopolymer. Furthermore, preferably the organic binder (6) may be mixed with organic binders which do not meet the definition of (6), as long as the average permittivity of the formulation is between 3.4 and 8.0.

In an even more preferred embodiment of the present invention, the organic binder comprises at least one unit having the structures (G) to (J):

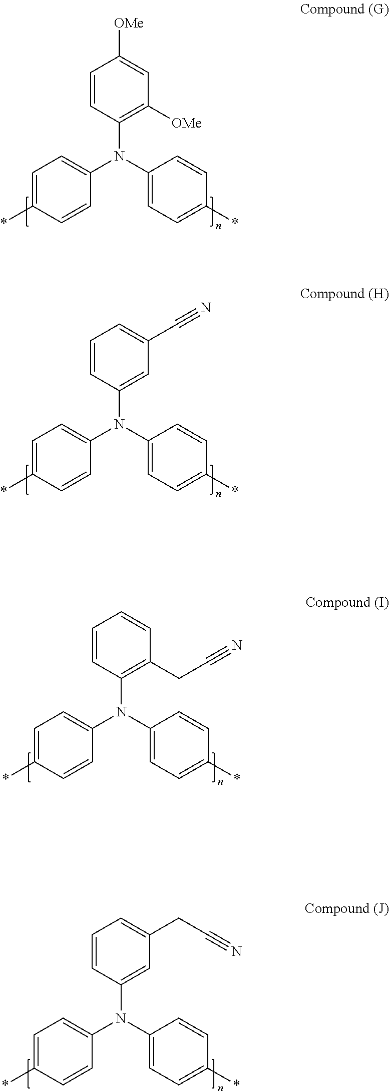

An organic binder according to the present invention may also be an arylamine-fluorene copolymer or an arylamine-indenofluorene copolymer such as those detailed in WO 2007/131582 or a polycyclic aromatic hydrocarbon copolymer semiconducting binder.

Polycyclic Aromatic Hydrocarbon Copolymers (hereinafter PAHCs) used in the present invention comprise a mixture of at least one polyacene monomer unit having the Formula (A), (B) or (C), and at least one monomer unit having the Formula (D), (E), (F), (G) or (H):

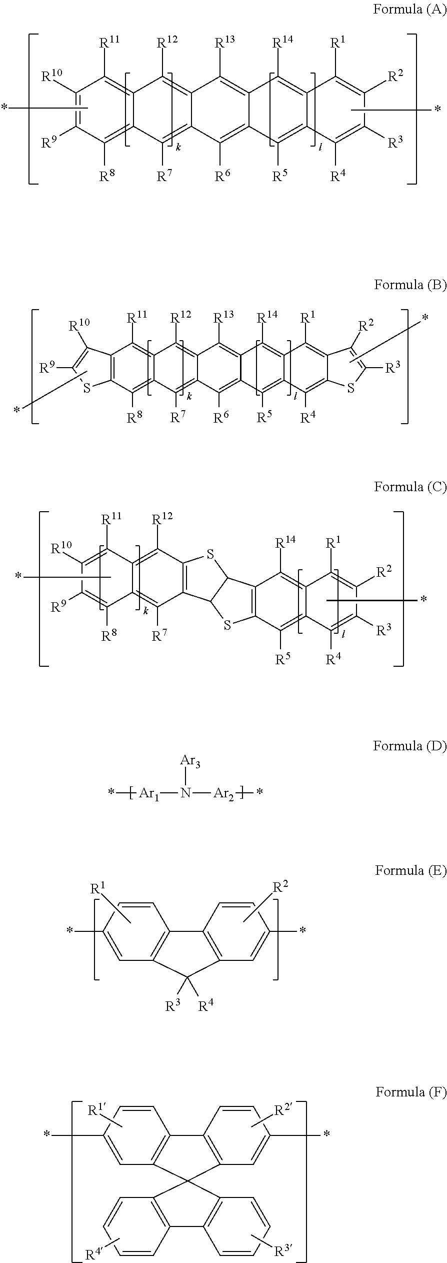

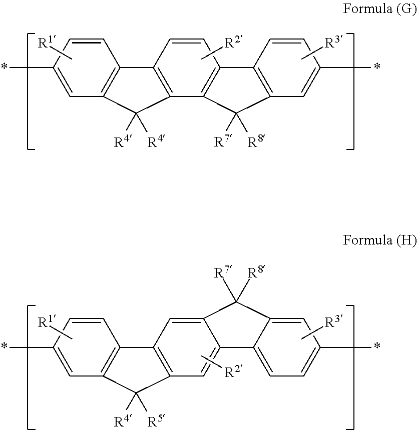

wherein each of R¹, R², R³, R⁴, R⁵, R⁶, R⁷, R⁸, R⁹, R¹⁰, R¹¹, R¹², R¹³ and R¹⁴, which may be the same or different, independently represents hydrogen; a branched or unbranched, substituted or unsubstituted C₁-C₄₀ alkyl group; a branched or unbranched, substituted or unsubstituted C₂-C₄₀ alkenyl group; a branched or unbranched, substituted or unsubstituted C₂-C₄₀ alkynyl group; an optionally substituted C₃-C₄₀ cycloalkyl group; an optionally substituted C₆-C₄₀ aryl group; an optionally substituted C₁-C₄₀ heterocyclic group; an optionally substituted C₁-C₄₀ heteroaryl group; an optionally substituted C₁-C₄₀ alkoxy group; an optionally substituted C₆-C₄₀ aryloxy group; an optionally substituted C₇-C₄₀ alkylaryloxy group; an optionally substituted C₂-C₄₀ alkoxycarbonyl group; an optionally substituted C₇-C₄₀ aryloxycarbonyl group; a cyano group (—CN); a carbamoyl group (—C(═O)NR¹⁵R¹⁶); a carbonyl group (—OC(═O)—R¹⁷); a carboxyl group (—CO₂R¹⁸) a cyanate group (—OCN); an isocyano group (—NC); an isocyanate group (—NCO); a thiocyanate group (—SCN) or a thioisocyanate group (—NCS); an optionally substituted amino group; a hydroxy group; a nitro group; a CF₃ group; a halo group (Cl, Br, F, I); —SR¹⁹; —SO₃H; —SO₂R²⁰; —SF₅; an optionally substituted silyl group; a C₂-C₁₀ alkynyl group substituted with a SiH₂R²² group, a C₂-C₁₀ alkynyl substituted with a SiHR²²R²³ group, or a C₂-C₁₀ alkynyl substituted with a —Si(R²²)ₓ(R²³)_{y}(R²⁴)_{z} group;
wherein each R²² group is independently selected from the group consisting of a branched or unbranched, substituted or unsubstituted C₁-C₁₀ alkyl group, a branched or unbranched, substituted or unsubstituted C₂-C₁₀ alkynyl group, a substituted or unsubstituted C₂-C₂₀ cycloalkyl group, a substituted or unsubstituted C₂-C₁₀ alkenyl group, and a substituted or unsubstituted C₆-C₂₀ cycloalkylalkylene group;
each R²³ group is independently selected from the group consisting of a branched or unbranched, substituted or unsubstituted C₁-C₁₀ alkyl group, a branched or unbranched, substituted or unsubstituted C₂-C₁₀ alkynyl group, a substituted or unsubstituted C₂-C₁₀ alkenyl group, a substituted or unsubstituted C₂-C₂₀ cycloalkyl group, and a substituted or unsubstituted C₆-C₂₀ cycloalkylalkylene group;
R²⁴ is independently selected from the group consisting of hydrogen, a branched or unbranched, substituted or unsubstituted C₂-C₁₀ alkynyl group, a substituted or unsubstituted C₂-C₂₀ cycloalkyl group, a substituted or unsubstituted C₆-C₂₀ cycloalkylalkylene group, a substituted C₅-C₂₀ aryl group, a substituted or unsubstituted C₆-C₂₀ arylalkylene group, an acetyl group, a substituted or unsubstituted C₃-C₂₀ heterocyclic ring comprising at least one of O, N, S and Se in the ring;
wherein x=1 or 2; y=1 or 2; z=0 or 1; and (x+y+z)=3;
wherein each of R¹⁵, R¹⁶, R¹⁸, R¹⁹ and R²⁰ independently represent H or optionally substituted C₁-C₄₀carbyl or hydrocarbyl group optionally comprising one or more heteroatoms;
wherein R¹⁷ represents a halogen atom, H or optionally substituted C₁-C₄₀ carbyl or C₁-C₄₀ hydrocarbyl group optionally comprising one or more heteroatoms;
wherein, independently, each pair of R² and R³ and/or R⁹ and R¹⁰, may be cross-bridged to form a C₄-C₄₀ saturated or unsaturated ring, which saturated or unsaturated ring may be intervened by an oxygen atom, a sulphur atom or a group shown by formula —N(R²¹)— (wherein R²¹ is a hydrogen atom or an optionally substituted C₁-C₄₀ hydrocarbon group), or may optionally be substituted; and wherein one or more of the carbon atoms of the polyacene skeleton may optionally be substituted by a heteroatom selected from N, P, As, O, S, Se and Te;
wherein independently any two or more of the substituents R¹-R¹⁴ which are located on adjacent ring positions of the polyacene may, together, optionally constitute a further C₄-C₄₀ saturated or unsaturated ring optionally interrupted by O, S or —N(R²¹) where R²¹ is as defined above; or an aromatic ring system, fused to the polyacene;
wherein k and I are independently 0, 1 or 2;
wherein at least two of R¹, R², R³, R⁴, R⁸, R⁹, R¹⁰ and R¹¹ are a bond, represented by [symbol] *, to another monomer unit having the Formula (A), (B), (C), (D), (E), (F), (G) or (H); and,
wherein Ar₁, Ar₂ and Ar₃, which may be the same or different, each represent, independently if in different repeat units, an optionally substituted C₆₋₄₀ aromatic group (mononuclear or polynuclear), wherein preferably at least one of Ar₁, Ar₂ and Ar₃ is substituted with at least one polar or polarising groups;
wherein each R_{1′}, R_{2′}, R^{3′}, R^{4′}, R^{5′}, R^{6′}, R^{7′}, R^{8′}, each of which may be the same or different, is selected from the same group as R¹, R², R³, R⁴, R⁵, R⁶, R⁷, R⁸; and for the monomer groups (D), (E), (F), (G) or (H), [symbol] * represents a bond to another monomer unit having the Formula (A), (B), (C), (D), (E), (F), (G) or (H).

Preferably, k=I=0 or 1.

Preferably, k=1 and I=1.

Preferably, x=2 and y=1.

Preferably when z=0, R²² and R²³ together comprise a combination of (i) branched or unbranched, substituted or unsubstituted C₁-C₈ alkyl group(s) and (ii) branched or unbranched, substituted or unsubstituted C₂-C₈ alkenyl group(s).

Preferably, any of R²², R²³ and R²⁴ may optionally be substituted with a halogen atom.

The copolymers used in the present invention preferably have a number average molecular weight (Mn) of between 300 and 100000, more preferably between 1600 and 20000, more preferably between 500 and 10000, even more preferably between 450 and 5000.

Preferably, the organic semiconductor formulations used in the present invention contain less than 10% by weight, more preferably less than 5% by weight, more preferably less than 1% of organic binders.

The organic binders according to the present invention preferably have a charge mobility value greater than μ=1×10⁻⁷ cm²V⁻¹ s⁻¹, and more preferably μ=1×10⁻⁶ cm²V⁻¹ s⁻¹ and still more preferably greater than μ=1×10⁻³ cm²V⁻¹ s⁻¹,

### Aromatic Hydrocarbon Solvent

An aromatic hydrocarbon solvent used in the present invention is preferably selected from the group consisting of C₆-C₁₈ aromatic hydrocarbons, preferably containing at least one 6 membered aromatic ring, and C₆-C₁₈ aromatic hydrocarbons substituted with 1 or 2 halogen atoms, and preferably containing at least one 6 membered aromatic ring. Preferably the halogen atoms are independently selected from chlorine or bromine.

Preferably, the aromatic hydrocarbon solvent used in the present invention is selected from the group consisting of C₆-C₁₀ aromatic hydrocarbons, preferably containing at least one 6 membered aromatic ring, and C₆-C₁₀ aromatic hydrocarbons substituted with 1 halogen atoms, and preferably containing at least one 6 membered aromatic ring. Preferably the halogen atoms are independently selected from chlorine or bromine, most preferably bromine.

Preferably, the aromatic hydrocarbon solvent used in the present invention is C₉-C₁₀ aromatic hydrocarbon, preferably containing at least one 6 membered aromatic ring.

Preferably, the aromatic hydrocarbon solvent used in the present invention is selected from the group consisting of tetralin, mesitylene, bromobenzeneandbromomesitylene.

Preferably, the aromatic hydrocarbon has a boiling point ≧150° C. and more preferably a boiling point ≧than 200° C. and ≦250° C.

### Further Solvents

The formulation according to the present invention further comprises at least one further solvent selected from the group consisting of aliphatic hydrocarbons; alcohols, polyols, aliphatic ketones, esters, amines, thiols and mixtures thereof.

More preferably, the further solvent is selected from the group consisting of aliphatic hydrocarbons and alcohols. The aliphatic hydrocarbons are preferably selected from C₄-C₁₀ aliphatic hydrocarbons, more preferably straight chain C₆-C₉ aliphatic hydrocarbons. The alcohols are preferably selected from C₁-C₆ alcohols, more preferably, C₂-C₄ alcohols, more preferably C₃-C₄ secondary alcohols. Suitable and preferred solvents include for example, n-hexane, n-octane, isopropanol or methyl ethyl ketone Preferably, the further solvent has a boiling point ≦150° C. and more preferably ≦100° C. Preferably, the aliphatic hydrocarbon has a boiling point ≦125° C. and more preferably ≦90° C.

The inclusion of a further solvent which is less solubilising of the polycrystalline small molecule can be used to control the crystal morphology of the polycrystalline small molecule when the OSC layer is formed on the substrate.

In particular, the boiling point and/or the surface tension of the further solvent can be used to produce uniformly distributed crystalline domains. This has the effect of producing transistors having high mobility and good device uniformity of electrical performance.

### Semiconductor Formulations

The multi-solvent OSC formulations of the invention following their deposition, surprisingly afford OSC layers having significantly better performance in transistors compared to OSC layers produced using the comparable single solvent formulation. The transistor devices incorporating the OSC layer of the invention have improvements in mobility of 150 to 250 percent compared to the single solvent formulation. Furthermore, the OTFTs of the invention have reduced threshold voltages (Vth). For the prior art single solvent layer the Vth is in the order of 15 to 20V compared to the more desirable value of 0-10V for the multi-solvent formulations of the present invention.

### Solubility of the OSCs in the Aromatic Hydrocarbon and Further Solvent(s)

The aromatic hydrocarbon solvent of the multi-solvent formulation is capable of dissolving at least 0.5% by weight of the polycrystalline small molecule of the present invention, more preferably greater than 1%.

The further (subsidiary) solvent(s) are preferably less solubilising of the polycrystalline small molecule and typically dissolve less than 0.2% by weight of the small molecule OSC, more preferably less than 0.1% by weight, more preferably less than 0.05% by weight.

The further solvent of the multi-solvent formulation preferably does not dissolve more than 0.1% by weight of the semiconducting binder of the present invention, more preferably not greater than 0.05%. Preferably, the semiconducting binder of the invention is essentially insoluble in the further solvent.

The solvents of the multi-solvent system are preferably fully miscible and when mixed with the small molecule OSC and the semiconducting binder form a stable, homogeneous solution.

### Relative Amounts of the Aromatic Hydrocarbon Solvent: Further Solvent(s)

The aromatic hydrocarbon solvent of the multi-solvent OSC formulation is preferably present at percentage volumes greater than 50% by volume of the total solvent blend and more preferably the main solvent comprises ≧60% by volume of the solvent blend by volume and still more preferably ≧70% by volume of the total solvent blend.

In a preferred embodiment, the aromatic hydrocarbon solvent is tetralin, and preferably comprises 80% of the solvent in the solvent blend (by volume). In this embodiment, the further solvent is preferably heptane. In this embodiment, the heptane preferably comprises 20% by volume of the solvent blend. Some examples (not intended to be limiting the invention) of the aromatic hydrocarbon solvent and further solvent(s) are included in Table 1 and Table 2 respectively.

### Relative Boiling Points of the Solvents

To achieve improved film coating properties and improved crystal morphology of the crystalline small molecule OSC, the aromatic hydrocarbon solvent of the OSC formulation of the invention preferably has a boiling point ≧150° C. and more preferably a boiling point ≧than 200° C. and ≦250° C.

The further solvent(s) used in the present invention preferably has a boiling point ≦125° C. and more preferably ≦100° C.

Preferably, the difference between the boiling point of the aromatic hydrocarbon solvent and the further solvent(s) is greater than 50° C., preferably greater than 70° C., more preferably greater than 80° C., more preferably greater than 100° C.

Surface Tension of the Solvents of the invention To achieve improved wetting of the preferred substrates of the invention, especially polyethylenenaphthalate (PEN), polyethylene terephthalate (PET), polyimide and SU8™ (Microchem), the further solvent(s) preferably has a surface tension <30 dyne/cm and still more preferably ≦25 dyne/cm, more preferably ≦24 dyne/cm.

Preferably, the surface tension of the multi-solvent blend is less than 35 dyne/cm, more preferably less than 32 dyne/cm.

Preferably, the difference between the surface tension of the aromatic hydrocarbon solvent and the further solvent(s) is greater than 5 dyne/cm, more preferably greater than 10 dyne/cm, more preferably greater than 12 dyne/cm.

Some examples of solvents suitable for use in the present invention are set forth below in Tables 1 and 2.

TABLE 1
Examples of Aromatic hydrocarbon Solvents

| | | | Solubility of | | | |
|---|---|---|---|---|---|---|
| | | | 1,4,8,11- | | | |
| | | | tetramethyl, 6,13- | | | |
| | Boiling | Surface | bis- | | Solubility of 4-Methoxy | |
| | Point | tension | (triethylsilylethynyl) | | polytriarylamine | |
| Main Solvent | (° C.) | (dyne/cm) | pentacene | | homopolymer | |
| Tetralin | 208 | 35.5 | 0.6% | w/v | <4% | w/v |
| 2-Bromomesitylene | 225 | 33.0 | 1.4% | w/v | <10% | w/v |
| Mesitylene | 165 | 28.8 | ~1% | w/v | ~1% | w/v |
| Bromobenzene | 156 | 36.5 | 3.5% | w/v | 1% | w/v |

TABLE 2
Examples of some ‘further’ Solvents

| | | | Solubility of 1,4,8,11- | |
|---|---|---|---|---|
| Subsidiary | | | tetramethyl, 6,13-bis- | Solubility of 4-Methoxy |
| (secondary) | | Surface | (triethylsilylethynyl) | polytriarylamine |
| Solvent | Boiling Point | tension | pentacene | homopolymer |
| n-Heptane | 98.4 | 20.0 | <0.1% | Insol. |
| n-Octane | 125 | 21.6 | <0.1% | Insol. |
| Cyclohexane | 81 | 25.0 | <0.1% | Insol. |
| Propan-2-ol | 82.5 | 23.7 | Insol. | Insol. |
| Methyl ethyl | 79.0-80.5 | 24.6 | Insol. | Insol. |
| ketone (MEK) | | | | |

TABLE 3
Some Examples of Multi-solvent Blends

| | Surface | | Surface |
|---|---|---|---|
| | tension | Surface tension | tension |
| | (Total) | Dispersive | Polar |
| Solvents (% volume: volume) | dyne/cm | dyne/cm | dyne/cm |
| Tetralin: n-heptane (80:20) | 30.5 | 23.8 | 6.7 |
| Tetralin: propan-2-ol (80:20) | 28.3 | 20.8 | 7.5 |
| Tetralin: tetrahydrofuran (80:20) | 33.2 | 26.1 | 7.1 |

Some preferred multi-solvent formulations include:

(i) 2 weight percent of 1,4,8,11-tetramethyl, 6,13-bis-(triethylsilylethynyl)pentacene and 4-Methoxy polytriarylamine homopolymer in ratio of 50:50 by weight dissolved in 80:20 by volume tetralin: n-heptane.
(ii) 2 weight percent of 1,4,8,11-tetramethyl, 6,13-bis-(triethylsilylethynyl)pentacene and 4-Methoxy polytriarylamine homopolymer in a ratio of 50:0 by weight dissolved in 70:30 by volume tetralin: n-heptane.
(iii) 2 weight percent of 1,4,8,11-tetramethyl, 6,13-bis-(triethylsilylethynyl)pentacene and 4-Methoxy polytriarylamine homopolymer in a ratio of 50:50 by weight dissolved in 80:20 by volume tetralin: propan-2-ol.
(iv) 2 weight percent of 1,4,8,11-tetramethyl, 6,13-bis-(triethylsilylethynyl)pentacene and 4-Methoxy polytriarylamine homopolymer in a ratio of 50:50 by weight dissolved in 70:30 by volume tetralin: propan-2-ol.
(v) 1.7 weight percent of 1,4,8,11-tetramethyl, 6,13-bis-(triethylsilylethynyl)pentacene and 4-Methoxy polytriarylamine homopolymer in a ratio of 25:75 by weight dissolved in 70:30 by volume tetralin: n-heptane.
(vi) 1.7 weight percent of 1,4,8,11-tetramethyl, 6,13-bis-(triethylsilylethynyl)pentacene and 4-Methoxy polytriarylamine homopolymer in a ratio of 25:75 by weight dissolved in 70:30 by volume tetralin: propan-2-ol.

### Organic Semiconductor Layers

The organic semiconductor formulation according to the present invention may be deposited onto a variety of substrates, to form organic semiconductor layers.

The organic semiconductor layer according to the present invention may be prepared using a method comprising the steps of:
(i) Providing the organic semiconductor formulation according to the present invention;
(ii) Depositing said formulation onto a substrate; and
(iii) Optionally removing the solvent to form an organic semiconductor layer.

Useful substrate materials include, but are not limited to, polymeric films such as polyamides, polycarbonates, polyimides, polyketones, polyethylene terephthalate (PET) and polyethylene naphthalate (PEN), and inorganic substrates such as silica, alumina, silicon wafers and glass. The surface of a given substrate may be treated, e.g. by reaction of chemical functionality inherent to the surface with chemical reagents such as silanes or exposure of the surface to plasma, in order to alter the surface characteristics.

Prior to depositing the organic semiconductor formulation onto the substrate, the formulation may be combined with one or more further solvents in order to facilitate the deposition step. Suitable solvents include, but are not limited to, anisole, morpholine, toluene, o-xylene, m-xylene, p-xylene, decalin and/or mixtures thereof.

In accordance with the present invention it has further been found that the level of the solids content in the organic semiconducting layer formulation is also a factor in achieving improved mobility values for electronic devices such as OFETs.

The solids content of the formulation is preferably 0.1 to 10% by weight, more preferably 0.5 to 5% by weight.

Suitable conventional deposition methods include, but are not limited to, spin coating, knife-coating, roll-to-roll web-coating, and dip coating, as well as printing processes such as ink-jet printing, screen printing, and offset lithography. In one desired embodiment, the resulting formulation is a printable formulation, even more desirably, an ink jet printable formulation.

Once the formulation is deposited onto a substrate surface, the solvent may be removed to form an organic semiconductor layer. Any suitable method may be used to remove the solvent. For example, the solvent may be removed by evaporation or drying. Typically, at least about 80 percent of the solvent is removed to form the semiconductor layer. For example, at least about 85 weight percent, at least about 90 weight percent, at least about 92 weight percent, at least about 95 weight percent, at least about 97 weight percent, at least about 98 weight percent, at least about 99 weight percent, or at least about 99.5 weight percent of the solvent is removed.

The solvent often can be evaporated at any suitable temperature. In some methods, the solvent mixture is evaporated at ambient temperature. In other methods, the solvent is evaporated at a temperature higher or lower than ambient temperature. For example, a platen supporting the substrate can be heated or cooled to a temperature higher or lower than ambient temperature. In still other preferred methods, some or most of the solvent can be evaporated at ambient temperature, and any remaining solvent can be evaporated at a temperature higher than ambient temperature. In methods where the solvent evaporates at a temperature higher than ambient temperature, the evaporation can be carried out under an inert atmosphere, such as a nitrogen atmosphere.

Alternatively, the solvent can be removed by application of reduced pressure (i.e., at a pressure that is less than atmospheric pressure) such as through the use of a vacuum. During application of reduced pressure, the solvent can be removed at any suitable temperature such as those described above.

The rate of removal of the solvent can affect the resulting semiconductor layer. For example, if the removal process is too rapid, poor packing of the semiconductor molecules can occur during crystallisation. Poor packing of the semiconductor molecules can be detrimental to the electrical performance of the semiconductor layer. The solvent can evaporate entirely on its own in an uncontrolled fashion (i.e., no time constraints), or the conditions can be controlled in order to control the rate of evaporation. In order to minimise poor packing, the solvent can be evaporated while slowing the evaporation rate by covering the deposited layer. Such conditions can lead to a semiconductor layer having a relatively high crystallinity.

After removal of a desired amount of solvent to form the semiconductor layer, the semiconductor layer can be annealed by exposure to heat or solvent vapours, i.e. by thermal annealing or solvent annealing.

### Electronic Devices

The invention additionally provides an electronic device comprising the organic semiconductor formulation according to the present invention. The formulation may be used, for example, in the form of a semiconducting layer or film.

Additionally, the invention preferably provides an electronic device comprising the organic semiconductor layer according to the present invention.

The thickness of the layer or film may be between 0.2 and 20 microns, preferably between 0.5 and 10 microns, between 0.5 and 5 microns and between 0.5 and 2 microns.

The electronic device may include, without limitation, organic field effect transistors (OFETS), organic light emitting diodes (OLEDS), photodetectors, organic photovoltaic (OPV) cells, sensors, lasers, memory elements and logic circuits.

Exemplary electronic devices of the present invention may be fabricated by solution deposition of the above-described organic semiconductor formulation onto a substrate.

### BRIEF DESCRIPTION OF THE DRAWINGS

Preferred organic electronic devices are OTFTs comprising the following components:
optionally a substrate (A)
a gate electrode (B)
a dielectric layer (C) (the dielectric layer (C), may optionally be crosslinked)
source and drain electrodes (E and F)
an OSC layer (D)
optionally a passivation layer (G)

FIG. 1 depicts a bottom gate (BG), bottom contact (BC) OTFT device according to the present invention.

FIG. 2 is a representation of top contact/bottom gate OTFT

FIG. 3 is a representation of bottom contact/bottom gate OTFT

FIG. 4 is a representation of top contact/top gate OTFT

FIG. 5 is a representation of bottom contact/top gate OTFT

FIG. 6 is the transfer characteristics for the multi-solvent OSC formulation of device 1, Ex 1

FIG. 7 is the output characteristics for the multi-solvent OSC formulation of device 1, Example 1

FIG. 8 is a cross polar optical micrograph of the mixed solvent formulation indicating that large crystalline domains are present which are uniformly distributed across the source and drain electrodes. This has the effect of producing transistors having high mobility and good device uniformity of electrical performance between the transistors across the substrate (low standard deviation of mobility values).

FIG. 9 is a cross polar optical micrograph of the single solvent formulation (prior art) indicating that much larger, non-uniform crystalline domains are present in the OSC layer, having ‘fractures’ within the crystalline domains. Characterisation of these TFTs affords approximately 33% mobility compared to the working example of the invention presented in FIG. 8, and has poor uniformity across the substrate.

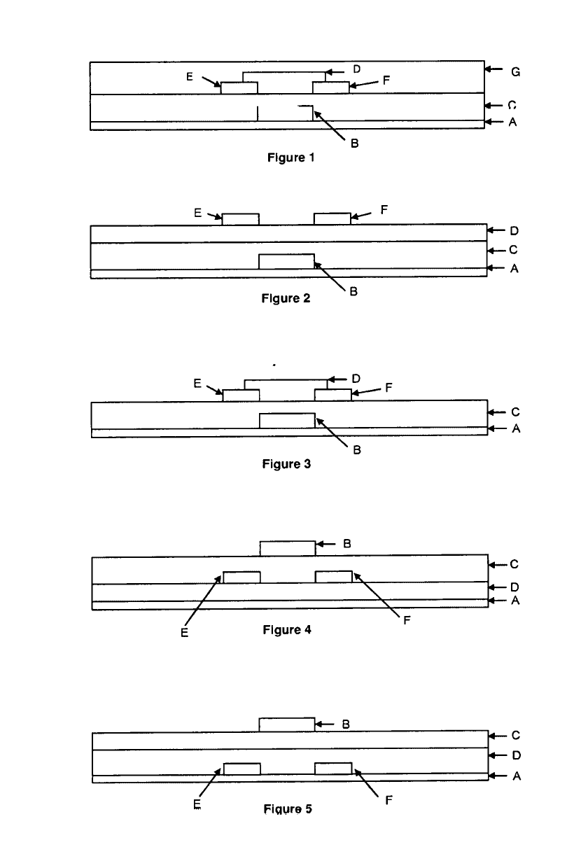

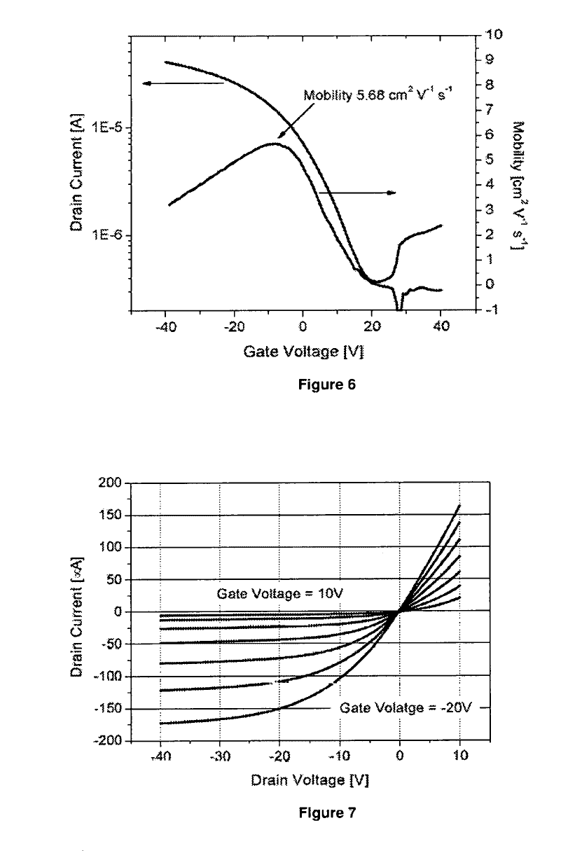

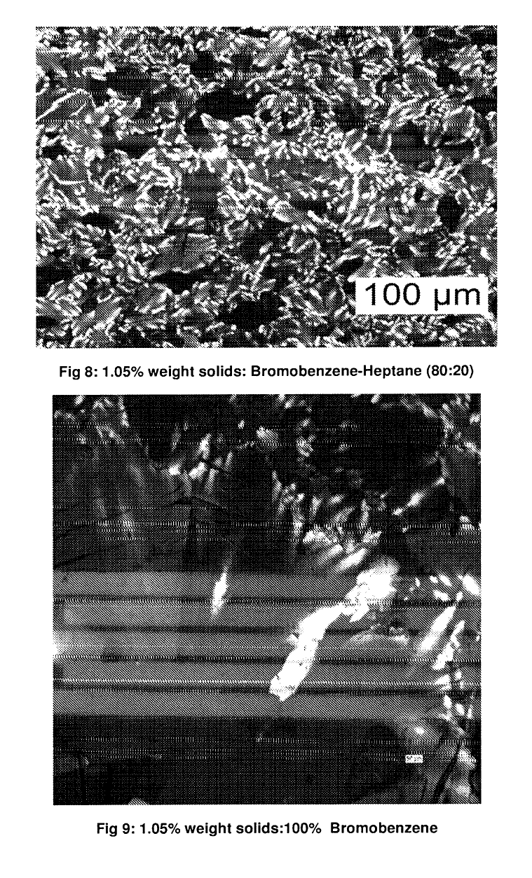

### TERMS AND DEFINITIONS

Throughout this specification, the words “comprise” and “contain” mean including but not limited to (and do not) exclude other components.

The term “polymer” includes homopolymers and copolymers, alternating or block co-polymers.

“Molecular weight” of a polymeric material (including monomeric or macromeric materials), as used herein, refers to the number-average molecular weight unless otherwise specifically noted or unless testing conditions indicate otherwise.

A “polymer” means a material formed by polymerising and/or crosslinking one or more monomers, macromers and/or oligomers and having two or more repeat units.

As used herein, the term “alkyl” group refers to a straight or branched saturated monovalent hydrocarbon radical, having the number of carbon atoms as indicated. By way of non-limiting example, suitable alkyl groups include, methyl, ethyl, propyl, n-butyl, t-butyl, iso-butyl and dodecanyl.

As used herein, the term “alkoxy” group include without limitation, methoxy, ethoxy, 2-methoxyethoxy, t-butoxy, etc.

As used herein, the term “amino” group includes, without limitation, dimethylamino, methylamino, methylphenylamino, phenylamino, etc.

The term “carbyl” refers to any monovalent or multivalent organic radical moiety which comprises at least one carbon atom other without any non-carbon atoms (—C≡C), or optionally combined with at least one non-carbon atoms such as N, O, S, P, SI, Se, As, Te or Ge (for example carbonyl etc.).

The term “hydrocarbon” group denotes a carbyl group that additionally contains one or more H atoms and optionally contains one or more hetero atoms.

A carbyl or hydrocarbyl group comprising 3 or more carbon atoms may be linear, branched and/or cyclic, including spiro and/or fused rings.

Preferred carbyl or hydrocarbyl groups include alkyl, alkoxy, alkylcarbonyl, alkylcarbonyloxy, alkoxycarbonyloxy, each of which is optionally substituted and has 1 to 40, preferably 1 to 18 carbon atoms, furthermore optionally substituted aryl, aryl derivative or aryloxy having 6 to 40, preferably 6 to 18 carbon atoms, furthermore alkylaryloxy, arylcarbonyl, aryloxycarbonyl, arylcarbonyloxy and aryloxycarbonyloxy, each or which is optionally substituted and has 7 to 40, more preferable 7 to 25 carbon atoms.

The carbyl or hydrocarbyl group may be saturated or unsaturated acyclic group, or a saturated or unsaturated cyclic group. Unsaturated acyclic or cyclic groups are preferred, especially alkenyl and alkynyl groups (especially ethynyl).

In the polyacenes of the present invention, the optional substituents on the said C₁-C₄₀carbyl or hydrocarbyl groups for R₁-R₁₄ etc. preferably are selected from: silyl, sulpho, sulphonyl, formyl, amino, imino, nitrilo, mercapto, cyano, nitro, halo, C₁₋₄ alkyl, C₆₋₁₂ aryl, C₁₋₄alkoxy, hydroxy and/or all chemically possible combinations thereof. More preferable among these optional substituents are silyl and C₆₋₁₂ aryl and most preferable is silyl.

“Substituted alkyl group” refers to an alkyl group having one or more substituents thereon, wherein each of the one or more substituents comprises a monovalent moiety containing one or more atoms other than carbon and hydrogen either alone (e.g., a halogen such as F) or in combination with carbon (e.g., a cyano group) and/or hydrogen atoms (e.g., a hydroxyl group or a carboxylic acid group).

“Alkenyl group” refers to a monovalent group that is a radical of an alkene, which is a hydrocarbon with at least one carbon-carbon double bond. The alkenyl can be linear, branched, cyclic, or combinations thereof and typically contains 2 to 30 carbon atoms. In some embodiments, the alkenyl contains 2 to 20, 2 to 14, 2 to 10, 4 to 10, 4 to 8, 2 to 8, 2 to 6, or 2 to 4 carbon atoms. Exemplary alkenyl groups include, but are not limited to, ethenyl, propenyl, and butenyl.

“Substituted alkenyl group” refers to an alkenyl group having (i) one or more C—C double bonds, and (ii) one or more substituents thereon, wherein each of the one or more substituents comprises a monovalent moiety containing one or more atoms other than carbon and hydrogen either alone (e.g., a halogen such as F) or in combination with carbon (e.g., a cyano group) and/or hydrogen atoms (e.g., a hydroxyl group or a carboxylic acid group).

“Alkynyl group” refers to a monovalent group that is a radical of an alkyne, a hydrocarbon with at least one carbon-carbon triple bond. The alkynyl can be linear, branched, cyclic, or combinations thereof and typically contains 2 to 30 carbon atoms. In some embodiments, the alkynyl contains 2 to 20, 2 to 14, 2 to 10, 4 to 10, 4 to 8, 2 to 8, 2 to 6, or 2 to 4 carbon atoms. Exemplary alkynyl groups include, but are not limited to, ethynyl, propynyl, and butynyl.

“Substituted alkynyl group” refers to an alkynyl group having (i) one or more C—C triple bonds, and (ii) one or more substituents thereon, wherein each of the one or more substituents comprises a monovalent moiety containing one or more atoms other than carbon and hydrogen either alone (e.g., a halogen such as F) or in combination with carbon (e.g., a cyano group) and/or hydrogen atoms (e.g., a hydroxyl group or a carboxylic acid group or a silyl group).

“Cycloalkyl group” refers to a monovalent group that is a radical of a ring structure consisting of 3 or more carbon atoms in the ring structure (i.e., only carbon atoms in the ring structure and one of the carbon atoms of the ring structure is the radical).

“Substituted cycloalkyl group” refers to a cycloalkyl group having one or more substituents thereon, wherein each of the one or more substituents comprises a monovalent moiety containing one or more atoms (e.g., a halogen such as F, an alkyl group, a cyano group, a hydroxyl group, or a carboxylic acid group).

“Cycloalkylalkylene group” refers to a monovalent group that is a ring structure consisting of 3 or more carbon atoms in the ring structure (i.e., only carbon atoms in the ring), wherein the ring structure is attached to an acyclic alkyl group (typically, from 1 to 3 carbon atoms, more typically, 1 carbon atom) and one of the carbon atoms of the acyclic alkyl group is the radical. “Substituted cycloalkylalkylene group” refers to a cycloalkylalkylene group having one or more substituents thereon, wherein each of the one or more substituents comprises a monovalent moiety containing one or more atoms (e.g., a halogen such as F, an alkyl group, a cyano group, a hydroxyl group, or a carboxylic acid group).

“Aryl group” refers to a monovalent group that is a radical of an aromatic carbocyclic compound. The aryl can have one aromatic ring or can include up to 5 carbocyclic ring structures that are connected to or fused to the aromatic ring. The other ring structures can be aromatic, non-aromatic, or combinations thereof. Examples of preferred aryl groups include, but are not limited to, phenyl, 2-tolyl, 3-tolyl, 4-tolyl, biphenyl, 4-phenoxyphenyl, 4-fluorophenyl, 3-carbomethoxyphenyl, 4-carbomethoxyphenyl, terphenyl, anthryl, naphthyl, acenaphthyl, anthraquinonyl, phenanthryl, anthracenyl, pyrenyl, perylenyl, and fluorenyl.

“Substituted aryl group” refers to an aryl group having one or more substituents on the ring structure, wherein each of the one or more substituents comprises a monovalent moiety containing one or more atoms (e.g., a halogen such as F, an alkyl group, a cyano group, a hydroxyl group, or a carboxylic acid group).

“Arylalkylene group” refers to a monovalent group that is an aromatic ring structure consisting of 6 to 10 carbon atoms in the ring structure (i.e., only carbon atoms in the ring structure), wherein the aromatic ring structure is attached to an acyclic alkyl group having one or more carbon atoms (typically, from 1 to 3 carbon atoms, more typically, 1 carbon atom) and one of the carbons of the acyclic alkyl group is the radical.

“Substituted arylalkylene group” refers to an arylalkylene group having one or more substituents thereon, wherein each of the one or more substituents comprises a monovalent moiety containing one or more atoms (e.g., a halogen such as F, an alkyl group, a cyano group, a hydroxyl group, or a carboxylic acid group).

“Acetyl group” refers to a monovalent radical having the formula —C(O)CH₃.

“Heterocyclic ring” refers to a saturated, partially saturated, or unsaturated ring structure comprising at least one of O, N, S and Se in the ring structure.

“Substituted heterocyclic ring” refers to a heterocyclic ring having one or more substituents bonded to one or more members of the ring structure, wherein each of the one or more substituents comprises a monovalent moiety containing one or more atoms (e.g., a halogen such as F, an alkyl group, a cyano group, a hydroxyl group, or a carboxylic acid group).

“Carbocyclic ring” refers to a saturated, partially saturated, or unsaturated ring structure comprising only carbon in the ring structure.

“Substituted carbocyclic ring” refers to a carbocyclic ring having one or more substituents bonded to one or more members of the ring structure, wherein each of the one or more substituents comprises a monovalent moiety containing one or more atoms (e.g., a halogen such as F, an alkyl group, a cyano group, a hydroxyl group, or a carboxylic acid group).

“Ether group” refers to a —Rₐ—O—R_{b} radical wherein Rₐ is a branched or unbranched alkylene, arylene, alkylarylene or arylalkylene hydrocarbon and R_{b} is a branched or unbranched alkyl, aryl, alkylaryl or arylalkyl hydrocarbon.

“Substituted ether group” refers to an ether group having one or more substituents thereon, wherein each of the one or more substituents comprises a monovalent moiety containing one or more atoms other than carbon and hydrogen either alone (e.g., a halogen such as F) or in combination with carbon (e.g., a cyano group) and/or hydrogen atoms (e.g., a hydroxyl group or a carboxylic acid group).

Unless otherwise defined, a “substituent” or “optional substituent” is preferably selected from the group consisting of halo (I, Br, Cl, F), CN, NO₂, NH₂, —COOH and OH.

Small molecule organic semiconductor means a discrete monomeric, non-polymeric compound crystalline organic semiconductor.

Unless stated otherwise, percentages of solids are percent by weight, percentages of ratios of liquids (for example in solvent mixtures) are percent by volume.

The values of surface tension are measured by the pendant drop technique using a computer controlled goniometer (e.g. OCA-15 from Dataphysics Instruments GmbH). A drop of the OSC formulation (of known density) is suspended from a needle in air and from the resulting drop profile the software calculates the surface tension using the Young-Laplace equation described in F. K. Hansen et al., Journal of Colloid and Interface Science, 141, (1991), pp 1-9. The surface tension can be resolved into polar and dispersive components through an additional interfacial tension measurement of the pendant drop of the OSC formulation in an immiscible liquid (such as a perfluorinated alkane of known density and surface tension) and by extrapolating the two components according to the method of Owens-Wendt described in D. K. Owens et al., Journal of Applied Polymer Science, 13, (1969), pp 1741-1747.

The total concentration of OSC compounds in the formulation is preferably from 0.1 to 10%, more preferably 0.5 to 5% by weight and still more preferably 0.5 to 3.0% by weight.

In the process of preparing the OTFT, the OSC layer is deposited onto a substrate, followed by removal of the solvents together with any volatile additives that may be present. The OSC layer is preferably deposited from the multi-solvent formulation by coating techniques described herein and known to those skilled in the art.

The substrate can be any substrate suitable for the preparation of organic electronic devices for example glass, polyethylene terephthalate (PET), polyethylene naphthalate (PEN) or polyimide.

In the case of preparing bottom gate OTFTs the surface to be coated with the multi-solvent formulation will be a gate insulator material, or an organic gate insulator (OGI). The OGI may be a crosslinkable material such as SU8 supplied by Microchem Corp. or a UV curable OGI such as those described herein and in patent WO2010/136385.

Removal of the solvent and any volatile additives is preferably achieved by evaporation, for example by exposing the deposited layer to high temperature and/or reduced pressure, preferably 60 to 150° C.

The thickness of the OSC layer is preferably from 10 nm to 5 microns, more preferably 50 nm to 2 microns, even more preferably 50 nm to 800 nm.

The solids content of the formulation is commonly expressed as follows:

$$Solid content ( \% ) = \frac{a + b}{a + b + c + d} \times 100 \qquad Equation 1$$

wherein: a=mass of polycrystalline small molecule OSC, b=mass of semiconducting binder, c=mass of aromatic hydrocarbon solvent 1, d=mass of further solvent 2.

For a three component solvent formulation, the solids content would be expressed by:

$$Solid content ( \% ) = \frac{a + b}{a + b + c + d + e} \times 100 \qquad Equation 2$$

wherein: a=mass of polycrystalline small molecule OSC, b=mass of semiconducting binder, c=mass of aromatic hydrocarbon solvent 1, d=mass of further solvent 2 and e-mass of further solvent 3.

Suitable conventional deposition methods include, but are not limited to, spin coating, Knife blade coating, roll-to-roll web-coating, and dip coating, as well as printing processes such as ink-jet printing, spray jet printing, screen printing, and offset lithography. In one desired embodiment, the resulting formulation is a printable formulation, even more desirably, an ink jet printable formulation.

The organic semiconductor layer according to the present invention preferably has a charge mobility value of at least 2.0 cm²V⁻¹ s⁻¹, preferably between 2 and 5.0 cm²V⁻¹ s⁻¹, more preferably between 4 and 10.0 cm²V⁻¹ s⁻¹ at transistor dimensions of W≦20000 microns and L≦550 microns respectively. The charge mobility value of the semiconductor layer can be measured using any standard method known to those skilled in the art, such as techniques disclosed in J. Appl. Phys., 1994, Volume 75, page 7954 and WO 2005/055248, preferably by those described in WO 2005/055248.

### OTFT Fabrication Method

A substrate (either glass or a polymer substrate such as PEN) is patterned with Au source drain electrodes either by a process of thermal evaporation through a shadow mask or by photolithography (an adhesion layer of either Cr or Ti is deposited on the substrate prior to deposition of Au). The Au electrodes can the optionally be cleaned using an O₂ plasma cleaning process. A solution of the multi-solvent organic semiconductor formulation is then applied by spin coating (the sample is flooded with the solution and the substrate is then spun at 500 rpm for 5 seconds then 1500 rpm for 1 minute). The coated substrate is then dried in air on a hot stage. The dielectric material, for example 3 wt % Teflon-AF 1600™ (Sigma-Aldrich cat #469610) dissolved in perfluorosolvent FC-43™) was then applied to the substrate by spin coating (sample flooded then spun at 500 rpm for 5 seconds then 1500 rpm for 30 seconds). The substrate was then dried in air on a hot stage (100° C. for 1 minute). A gate electrode (Au) is then defined over the channel area by evaporation through a shadow mask.

The mobility of the OTFT for the formulations is characterised by placing on a semi-auto probe station connected to a Keithley SCS 4200 semiconductor analyzer. The source drain voltage is set at −2V and the gate voltage scanned from +20V to −40V. Drain current is measured and the mobility is calculated from the transconductance.

In the linear regime, when |V_{G}|>|V_{DS}|, the source-drain current varies linearly with V_{G}. Thus the field effect mobility (μ) can be calculated from the gradient (S) of I_{DS} vs. V_{G} given by equation 3 (where Cᵢ is the capacitance per unit area, W is the channel width and L is the channel length):

$$S = \frac{μ {WC}_{i} {V}_{DS}}{L} \qquad Equation 3$$

In the saturation regime, the mobility is determined by finding the slope of I_{DS}^{1/2} vs. V_{G} and solving for the mobility (Equation 4):

$${I}_{DS} \approx \frac{{WC}_{i} {μ ( {V}_{GS} - {V}_{T} )}^{2}}{2 L} \qquad Equation 4$$

The invention will now be described in more detail by reference to the following examples, which are intended to be illustrative only and not limiting to the scope of the invention.

Polyacene compounds according to the present invention may be synthesised by any known method within the common general knowledge of a person skilled in the art. In a preferred embodiment, methods disclosed in US 2003/0116755 A, U.S. Pat. No. 3,557,233, U.S. Pat. No. 6,690,029 WO 2007/078993, WO 2008/128618 and Organic Letters, 2004, Volume 6, number 10, pages 1609-1612 can be employed for the synthesis of polyacene compounds according to the present invention.

### EXAMPLES OF THE PRESENT INVENTION

The following examples of the present invention are merely exemplary and should not be viewed as limiting the scope of the invention.

### Example 1

A formulation comprising a 50:50 blend of 1,4,8,11-tetramethyl, 6,13-bis(triethylsilylethynyl)pentacene: 4-methoxy polytriarylamine binder at a total solids loading of 2.1 wt percent in 80 Tetralin: 20 Heptane (by volume) was used to prepare a Top Gate, Bottom Contact OTFT array.

### Preparation of the Formulation and OTFT

The 4-methoxy-PTAA homopolymer was synthesised according to the method described in PCT/GB2012/051213. The resulting 4-methoxy polytriarylamine polymer had a Mn of ˜1315 Daltons and an Nₐᵥ of ˜5.

The multi-solvent formulation of Example 1 was prepared by fully dissolving 4-methoxy polytriarylamine binder (50 mg) and 1,4,8,11-tetramethyl, 6,13-bis(triethylsilylethynyl) pentacene (50 mg), (50:50 ratio by weight) in 1,2,3,4-tetrahydronaphthalene (tetralin, 4.0 ml) and n-heptane (1.0 ml) at a total solids loading of 2.1%. The formulation was spin coated (500 rpm for 5 s, then 2000 rpm for 20 s) onto PEN patterned with Au source/drain electrodes (50 nm thick Au treated with a 10 mM solution of pentafluorobenzenethiol in isopropyl alcohol). The resulting OSC layer was heated for 60 seconds at 100° C. and subsequently cooled. The fluoropolymer dielectric Cytop™ (Asahi Chemical Co.) was spin coated on top of the OSC layer (500 rpm for 5 s then 1500 rpm for 20 s). Finally, a 50 nm thick Al gate electrode was thermally evaporated through a shadow mask and the resulting OTFT array was characterised and the results obtained are summarised in Table 1.

### OTFT Results: Example 1

TABLE 1

| | Channel | Channel | | |
|---|---|---|---|---|
| | Width | length | | Threshold |
| Device | (microns, | (microns, | Mobility | Voltage, |
| Number | μm) | μm) | (cm² · V⁻¹s⁻¹) | Vth (V) |
| 1 | 500 | 10 | 5.7 | 6.8 |
| 2 | 1000 | 15 | 5.4 | 7.4 |
| 3 | 1500 | 30 | 5.3 | 7.2 |

### Comparative Example A

A formulation comprising a 50:50 blend of 1,4,8,11-tetramethyl, 6,13-bis(triethylsilylethynyl)pentacene: 4-methoxy polytriarylamine binder at 2 wt percent solids in 100% tetralin was used to fabricate a Top Gate, Bottom Contact OTFT array.

The 4-methoxy-PTAA homopolymer was synthesised according to the method described in PCT/GB2012/051213. The resulting 4-methoxy polytriarylamine polymer had an Mn of ˜2400 Daltons and an Nₐᵥ of ˜9.

### Formulation A

The single solvent OSC formulation was prepared by dissolving 4-methoxypolytriarylamine and 1,4,8,11-tetramethyl-6,13-bis(triethylsilylethynyl) pentacene (50:50 ratio by weight) in tetralin at 2% total solids. The resulting formulation was spin coated (500 rpm for 5 s, then 1500 rpm for 60 s) onto patterned Au source/drain electrodes (50 nm thick Au treated with a 10 mM solution of pentafluorobenzenethiol in isopropyl alcohol). The fluoropolymer dielectric Cytop™ (Asahi Chemical Co.) was spin coated on top of the OSC layer (500 rpm for 5 s, then 1500 rpm for 20 s). Finally an Au gate electrode was deposited by shadow mask evaporation and the TFT array was characterised as described in Table A.

TABLE A
OTFT Results:

| | | Channel | |
|---|---|---|---|
| Device | Channel Width | length | Mobility |
| Number | (microns, μm) | (microns, μm) | (cm² · V⁻¹s⁻¹)) |
| 1 | 15000 | 10 | 2.3 |
| 2 | 15000 | 30 | 3.0 |
| 3 | 15000 | 100 | 2.2 |

### Example 2

A formulation comprising a 70:30 blend of the PAHC random copolymer, TIPS pentacene: 9,9-dioctylfluorene copolymer 1,4,8,11-tetramethyl-6,13-bis(triethylsilylethynyl)pentacene at 1.7 wt percent solids in 80:20 tetralin:heptane (by volume) was used to prepare a Top Gate, Corbino OTFT array.

### Preparation of the Formulation and OTFT

The TIPS pentacene: 9,9-dioctylfluorene copolymer binder was synthesised according to the method described in PCT/GB2013/050458. The resulting TIPS pentacene: 9,9-dioctylfluorene copolymer (75% dioctylfluorene:25% TIPS pentacene) had an Mn of ˜8190 Daltons and an Nₐᵥ of ˜18.

A multi-solvent formulation was prepared comprising the TIPS pentacene:dioctylfluorene binder (60.0 mg) and 1,4,8,11-tetramethyl-6,13-bis(triethylsilylethynyl)pentacene (25 mg), (70:30 ratio by weight) by fully dissolving the copolymer and the polycrystalline small molecule in tetralin (4.0 ml) and n-heptane (1.0 ml) at 1.7% total solids

Corbino devices were fabricated at the CPI Printable Electronics Centre (UK). The resulting OTFTs were then characterised and afforded the results summarised in Table 2.

TABLE 2

| | Channel | Channel | | Standard | Number of | Threshold |
|---|---|---|---|---|---|---|
| Device | Width | length | Mobility | deviation of | devices | Voltage, |
| Number | (microns, μm) | (microns, μm) | (cm^{2.}V⁻¹s⁻¹) | mobility (%) | tested | Vth (V) |
| 1 | 1115 | 5 | 2.3 | 15 | 20 | 1.0 |
| 2 | 1100 | 10 | 2.8 | 11 | 20 | 1.2 |
| 3 | 1068 | 20 | 3.1 | 20 | 16 | 1.4 |
| 9 | 1005 | 40 | 4.0 | 16 | 20 | 2.0 |

### Example 3

A formulation comprising a 2:1 blend of 1,4,8,11-tetramethyl, 6,13-bis(triethylsilylethynyl)pentacene: 4-methoxy polytriarylamine binder at 1.05 wt percent solids in 80:20 bromobenzene:heptane (by volume) was used in a Bottom Gate, Bottom Contact OTFT

### Preparation of the Formulation and OTFT

The 4-methoxy-PTAA homopolymer was synthesised according to the method described in PCT/GB2012/051213. The resulting 4-methoxypolytriarylaminepolymer had an Mn of ˜1315 Daltons and an Nav of ˜5.

A multi-solvent formulation was prepared comprising 4-methoxy polytriarylamine binder (17.5 mg) and 1,4,8,11-tetramethyl, 6,13-bis(triethylsilylethynyl)pentacene (35 mg), (1:2 ratio by weight) by fully dissolving bromobenzene (4.0 ml) and n-heptane (1.0 ml) at 1.05% total solids. The formulation was spin coated (2000 rpm for 60 s) onto 15 mm square patterned silicon wafer substrates (obtained from Fraunhofer IPMS); the gate electrode is N-doped silicon with a 230 nm thick oxide as the gate insulator. A protective layer of photoresist was removed by soaking and rinsing in acetone. The substrates were placed in an oxygen plasma (250 W) for 5 minutes. The substrate was then treated with a 25 mM solution of phenethyltrichlorosilane in toluene followed by a solution of 10 mM pentafluorobenzenethiol). After spin coating the multi-solvent formulation, the substrate was dried on a hotplate for 1 minute at 100° C. Devices were then encapsulated with the fluoropolymer Cytop™ (Asahi Chemical Co.) by spin-coating (1500 rpm for 20 s) and baking for 60 s on a hotplate set to 100° C. The resulting OTFT was then characterised and afforded the results summarised in Table 3.

TABLE 3

| | | Channel | |
|---|---|---|---|
| Device | Channel Width | length | Mobility |
| Number | (microns, μm) | (microns, μm) | (cm² · V⁻¹s⁻¹) |
| 2 | 2000 | 5 | 2.0 |
| 3 | 2000 | 10 | 1.9 |

We claim:

1. A multi-solvent Organic semiconductor (OSC) formulation comprises:
(a) a polycrystalline small molecule organic semiconductor;
(b) an organic semiconductor binder;
(c) an aromatic hydrocarbon solvent; and
(d) at least one further solvent selected from the group consisting of aliphatic hydrocarbons, alcohols, polyols, aliphatic ketones, esters, amines, thiols and mixtures thereof.

2. The formulation according to claim 1, wherein the polycrystalline small molecule organic semiconductor comprises a polyacene compound.

3. The formulation according to claim 1, wherein the organic semiconductor binder comprises a polytriarylamine binder.

4. The formulation according to claim 1, wherein the organic semiconductor binder is selected from the group consisting of arylamine-fluorene copolymer; an arylamine-indenofluorene copolymer and a polycyclic aromatic hydrocarbon copolymer semiconducting binder.

5. The formulation according to claim 1, wherein the aromatic hydrocarbon solvent is selected from the group consisting of C₆-C₁₈ aromatic hydrocarbons, and C₆-C₁₈ aromatic hydrocarbons substituted with 1 or 2 halogen atoms, preferably wherein the halogen atom(s) are independently selected from chlorine and bromine.

6. (canceled)

7. The formulation according to claim 1, wherein the aromatic hydrocarbon solvent is selected from the group consisting of C₆-C₁₀ aromatic hydrocarbons, and C₆-C₁₀ aromatic hydrocarbons substituted with 1 halogen atom.

8. The formulation according to claim 1, wherein the aromatic hydrocarbon solvent is selected from the group consisting of tetralin, mesitylene, bromobenzene, bromomesitylene and mixtures thereof.

9. The formulation according to claim 1, wherein the aromatic hydrocarbon has a boiling point ≧150° C., preferably ≧than 200° C. and ≦250° C.

10. The formulation according to claim 1, wherein the at least one further solvent is selected from the group consisting of aliphatic hydrocarbons and alcohols, preferably wherein the aliphatic hydrocarbon is selected from C₄-C₁₀ aliphatic hydrocarbons, preferably straight chain C₆-C₉ aliphatic hydrocarbons, and preferably wherein the alcohol is selected from C₁-C₆ alcohols, preferably C₂-C₄ alcohols, more preferably C₃-C₄ secondary alcohols.

11. (canceled)

12. (canceled)

13. The formulation according to claim 1, wherein the further solvent is selected from the group consisting of n-hexane, octane, isopropanol and mixtures thereof.

14. The formulation according to claim 1, wherein the further solvent has a boiling point ≦125° C., preferably ≦100° C.

15.-17. (canceled)

18. The formulation according to claim 1, wherein the solvents of the multi-solvent system are miscible.

19. (canceled)

20. (canceled)

21. The formulation according to claim 1, wherein the difference between the boiling point of the aromatic hydrocarbon solvent and the further solvent is greater than 50° C.

22. The formulation according to claim 1, wherein the further solvent has a surface tension <30 dyne/cm, preferably ≦25 dyne/cm, and still more preferably ≦24 dyne/cm.

23. The formulation according to claim 1, wherein the surface tension of the multi-solvent blend is less than 35 dyne/cm, more preferably less than 32 dyne/cm.

24. (canceled)

25. A method of forming the organic semiconductor layer, comprising the steps of:
(i) Providing an organic semiconductor formulation according to claim 1;
(ii) Depositing said formulation onto a substrate; and
(iii) Optionally removing the solvent to form an organic semiconductor layer.

26. The method according to claim 25, wherein said substrate is selected from the group consisting of polymeric films such as polyamides, polycarbonates, polyimides, polyketones, polyethylene terephthalate (PET) and polyethylene naphthalate (PEN), and inorganic substrates such as silica, alumina, silicon wafers and glass.

27. The method according to claim 25, further comprising the step of providing a solvent selected from the group consisting of tetrahydrofuran, anisole, morpholine, toluene, o-xylene, m-xylene, p-xylene, decalin and/or mixtures thereof.

28. (canceled)

29. (canceled)

30. A semiconductor layer obtainable by the method according to claim 25.

31. An electronic device comprising the organic semiconductor formulation or layer according to claim 1, preferably wherein said device is selected from the group consisting of organic field effect transistors (OFETS), integrated circuits, organic light emitting diodes (OLEDS), photodetectors, organic photovoltaic (OPV) cells, sensors, lasers, memory elements and logic circuits.

32. (canceled)

33. An ink-jet formulation containing a formulation according to claim 1.
